(19) United States
(12) Patent Application Publication
(10) Pub. No.: US 2026/0072058 A1
(43) Pub. Date: Mar. 12, 2026

(54) SENSOR DEVICES AND ASSOCIATED PRODUCTION METHODS

(71) Applicant: Infineon Technologies AG, Neubiberg (DE)

(72) Inventors: Horst THEUSS, Wenzenbach (DE); Rainer Markus SCHALLER, Aichen (DE)

(21) Appl. No.: 19/306,302

(22) Filed: Aug. 21, 2025

(30) Foreign Application Priority Data
Sep. 6, 2024 (DE) 102024125647.8

(51) Int. Cl. G01R 15/20

(52) U.S. Cl. CPC G01R 15/207; G01R 15/202; G01R 15/205

(57) ABSTRACT

A sensor device contains a current conductor with a recess, wherein the current conductor is configured to conduct an electric current. The sensor device further contains a magnetic field sensor chip, which is arranged in the recess on a mounting surface of the current conductor and is configured to detect a magnetic field generated by the electric current. The current conductor and the magnetic field sensor chip are galvanically isolated from each other.

### CROSS REFERENCE TO RELATED APPLICATION

This application claims priority to Germany Patent Application No. 102024125647.8 filed on Sep. 6, 2024, the content of which is incorporated by reference herein in its entirety.

### TECHNICAL FIELD

The present disclosure relates to sensor devices and methods for producing sensor devices.

### BACKGROUND

Magnetic field sensors can be used to measure the strength of an electrical current flowing through a busbar (or current conductor). In some cases, the busbar may be part of a leadframe on which the magnetic field sensor is arranged. Both the busbar and the magnetic field sensor can be embedded in an encapsulation material.

Manufacturers and developers of sensor devices are constantly striving to improve their products. It may be of interest to provide smaller and more cost-effective solutions than those already known. In addition, it may be of interest to provide suitable methods for producing such sensor devices.

### SUMMARY

Various aspects relate to a sensor device. The sensor device includes a current conductor with a recess, wherein the current conductor is configured to conduct an electric current. The sensor device further includes a magnetic field sensor chip, which is arranged in the recess on a mounting surface of the current conductor and is configured to detect a magnetic field generated by the electric current. The current conductor and the magnetic field sensor chip are galvanically isolated from each other.

Various aspects relate to a method for producing a sensor device. The method includes forming a current conductor with a recess, wherein the current conductor is configured to conduct an electric current. The method further includes arranging a magnetic field sensor chip in the recess on a mounting surface of the current conductor, wherein the magnetic field sensor chip is configured to detect a magnetic field generated by the electric current. The current conductor and the magnetic field sensor chip are galvanically isolated from each other.

A person skilled in the art will discern further features and advantages of the implementation upon reading the following detailed description and examining the attached drawings.

### BRIEF DESCRIPTION OF THE DRAWINGS

The present disclosure is shown in an example and non-limiting manner in the illustrations of the attached drawings, in which identical reference signs refer to similar or identical elements. The elements in the drawings are not necessarily depicted to scale in relation to each other. The features of the various examples shown can be combined, provided that they are not mutually exclusive.

FIG. 1 shows a side cross-sectional view of a sensor device 100 according to the disclosure.

FIG. 2 shows a plan view of a sensor device 200 according to the disclosure.

FIG. 3 shows a plan view of a sensor device 300 according to the disclosure.

FIG. 4 shows a perspective view of a sensor device 400 according to the disclosure.

FIG. 5 shows a side cross-sectional view of a sensor device 500 according to the disclosure.

FIGS. 6A and 6B show a plan view and a view from below of a sensor device 600 according to the disclosure.

FIGS. 7A and 7B show a plan view and a view from below of a sensor device 700 according to the disclosure.

FIGS. 8A and 8B show a plan view and a view from below of a sensor device 800 according to the disclosure.

FIGS. 9A and 9B show a plan view and a view from below of a sensor device 900 according to the disclosure.

FIG. 10 illustrates a concept for measuring an electric current using a sensor device 1000 according to the disclosure.

FIG. 11 shows a flowchart of a method for producing a sensor device according to the disclosure.

### DETAILED DESCRIPTION

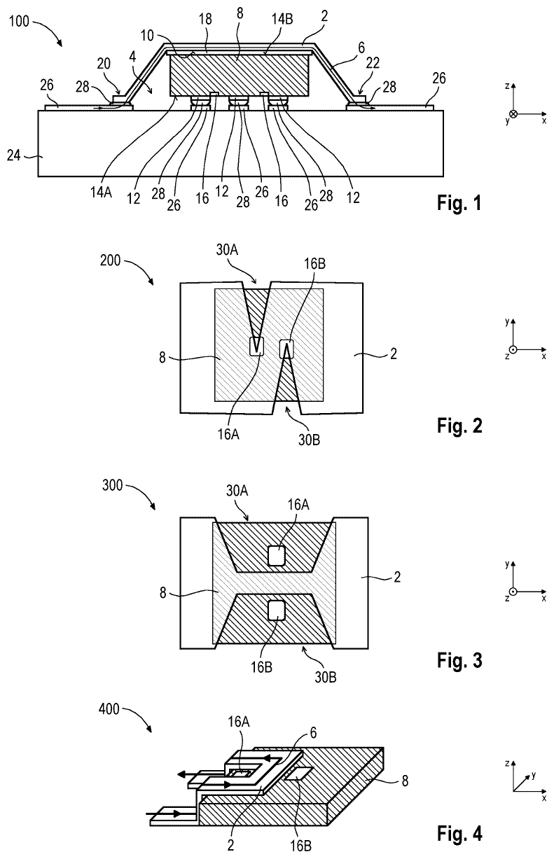

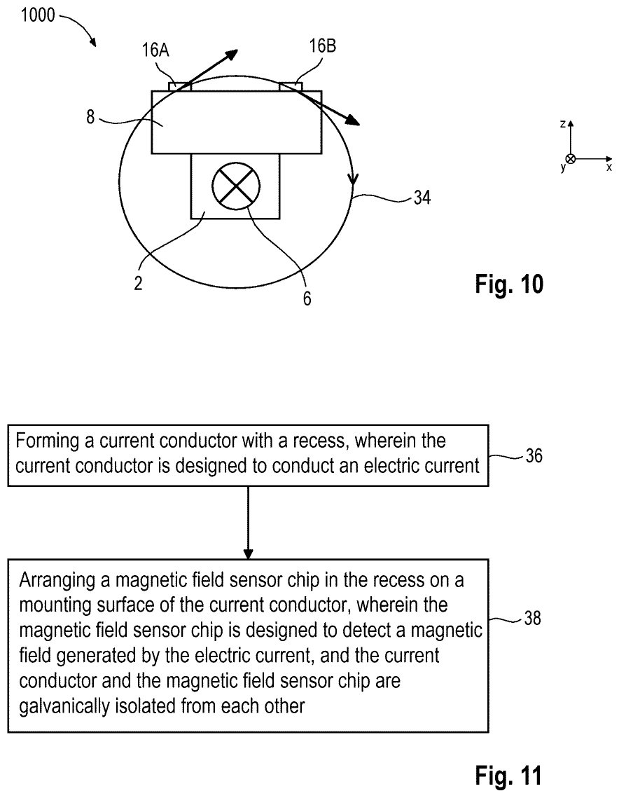

The sensor device 100 of FIG. 1 may comprise a current conductor 2 having a recess 4, wherein the current conductor 2 may be configured to conduct an electric current (or measuring current) 6. In some cases, the current conductor 2 can also be referred to as a busbar. Further, the sensor device 100 may comprise a magnetic field sensor chip 8, which is arranged in the recess 4 on a mounting surface 10 of the current conductor 2 and can be configured to detect a magnetic field generated by the electric current 6. The current conductor 2 and the magnetic field sensor chip 8 can be galvanically isolated from each other. The sensor device 100 can be configured to measure an intensity of the electric current 6. An example non-limiting measurement concept is described in connection with FIG. 10.

The magnetic field sensor chip 8 may contain or be made of any semiconductor material, for example silicon. The magnetic field sensor chip 8 can be an integrated circuit, so that it may also be referred to as a magnetic field sensor IC. In the example shown, the magnetic field sensor chip 8 may in particular be an unpackaged bare chip (“bare die”), which must not necessarily be arranged in a housing, but can be used without such a housing. In this description, the terms “die”, “chip”, “semiconductor die” and “semiconductor chip” may be used interchangeably. In the example shown, the magnetic field sensor chip 8 can be attached to the mounting surface 10 of the current conductor 2 by an adhesive layer 18. The adhesive layer 18 may be electrically insulating to provide galvanic isolation between the current conductor 2 and the magnetic field sensor chip 8. In one example, the adhesive layer 18 may be configured as an adhesive layer or adhesive film.

The magnetic field sensor chip 8 may have one or more electrical contacts 12, which may be arranged on a first surface 14A of the magnetic field sensor chip 8. The first surface 14A may be referred to in some examples as the front side of the magnetic field sensor chip 8. In the case shown, the first surface 14A with the electrical contacts 12 can face away from the mounting surface 10 of the current conductor 2. The electrical contacts 12 can be electrically coupled with internal electronic structures of the magnetic field sensor chip 8, e.g., the electronic structures can be electrically contacted via the electrical contacts 12. Furthermore, the magnetic field sensor chip 8 in the case shown on a second surface 14B of the magnetic field sensor chip 8 facing the mounting surface (10) can be free of electrical contacts. The second surface 14B may be referred to in some examples as the reverse of the magnetic field sensor chip 8.

The magnetic field sensor chip 8 may comprise one or more sensor elements 16 arranged on its first surface 14A. In the case shown, an example and non-limiting number of two sensor elements 16 is shown. In this case, the magnetic field sensor chip 8 may, for example, be a differential magnetic field sensor chip, the operating principle of which is described in connection with FIG. 10. Each of the sensor elements 16 may be configured to detect a magnetic field present at the location of the respective sensor element 16. It should be noted here that the magnetic field sensor chip 8 or its sensor elements 16 do not have to be limited to a specific or single sensor technology. The sensor elements 16 may be embodied, for example, as Hall sensor elements, magnetoresistive sensor elements, vertical Hall sensor elements or Fluxgate sensor elements. An xMR magnetoresistive sensor element may be an AMR (anisotropic magneto-resistive) sensor element, a GMT (giant magneto-resistive) sensor element, or a TMR (tunnel magneto-resistive) sensor element. In the example shown, the respective sensor element 16 may be configured in particular to detect a magnetic field component running perpendicular to the front side 14A of the magnetic field sensor chip 8. In this context, the respective sensor element 16 may be sensitive in the z direction, for example, e.g., may be configured to detect a magnetic field component in the z direction. Optionally, the sensor elements 16 can also be sensitive with respect to other spatial directions. Measurement signals based on the detected magnetic field components may be output from the sensor device 100 to external components (not shown), for example via the electrical contacts 12.

In the example shown, both the electrical contacts 12 and the sensor elements 16 may be arranged on the first surface 14A, which faces away from the mounting surface 10. In further examples, at least one (or all) of the sensor elements 16 may be arranged on the second surface 14B of the magnetic field sensor chip 8, which is facing the mounting surface 10. In such a case, the magnetic field sensor chip 8 may have one or more electrical connections (not shown), which may extend from the first surface 14A to the second surface 14B of the magnetic field sensor chip 8 and can electrically connect sensor elements 16 on the reverse side 14B to electrical contacts 12 on the front side 14A. Via these electrical connections, measurement signals provided by the sensor elements 16 can thus be routed downwards to the electrical contacts 12. For example, such electrical connections may be TSVs (through silicon vias), which may extend through the semiconductor material of the magnetic field sensor chip 8. If the magnetic field sensor chip 8 is embedded in an encapsulation material, the electrical connections may extend at least partially through the encapsulation material. In an arrangement of the sensor elements 16 on the reverse side 14B, the sensor elements 16 may on the one hand be located closer to the current conductor 2, where the magnetic field generated by the electric current 6 can have a stronger value, so that improved measurement results can be achieved. On the other hand, the additionally required electrical connections (e.g., TSVs) can complicate the manufacture of the sensor device 100 and/or make it more expensive.

The current conductor 2 may be produced from a material which, on the one hand, may have a good electrical conductivity in order to be able to conduct the electric current 6 sufficiently well. On the other hand, the material of the current conductor 2 may also be suitable for promoting a favorable and efficient production of the recess 4. For example, the current conductor 2 can be deep-drawn and/or stamped to form the recess 4, e.g., the material can provide, for example, a suitable elasticity for carrying out such method steps. In some examples, the conductor 2 can contain or be manufactured from copper, copper alloys, aluminum, aluminum alloys, nickel silver or the like.

The current conductor 2 may have the shape of a shell or trough, wherein the magnetic field sensor chip 8 may be arranged on a bottom surface of the shell or trough. In the example shown, the bottom surface of the shell or trough can correspond to or contain the mounting surface 10 of the current conductor 2. The magnetic field sensor chip 8 may be arranged completely in the recess 4 of the current conductor 2. The magnetic field sensor chip 8 can be recessed in the z-direction in the recess 4 up to its entire height. A dimension of the recess 4 in the z-direction may be greater than a dimension of the magnetic field sensor chip 8 (with or without the electrical contacts 12) in the z-direction. The current conductor 2 can extend over the reverse side 14B of the magnetic field sensor chip 8 and at least partially cover it. Against this background, the current conductor 2 can also be referred to as a lid or cover. The current conductor 2 and at least one lateral surface of the magnetic field sensor chip 8 may be spaced apart from each other, in particular to prevent electrical flashovers between these components. Optionally, an electrically insulating material (not shown in FIG. 1) may be arranged in the recess 4 between the current conductor 2 and at least one lateral surface of the magnetic field sensor chip 8 in order to minimize the risk of electrical flashovers.

The current conductor 2 and the electrical contacts 12 of the magnetic field sensor chip 8 can be arranged substantially in a common plane, which can also be referred to as the mounting plane (or mounting surface) of the sensor device 100. In particular, a current input 20 of the current conductor 2, a current output 22 of the current conductor 2 and at least one electrical contact 12 of the magnetic field sensor chip 8 are arranged substantially in the same plane. In this context, the sensor device 100 can be in particular a surface mounted device (SMD). In the example shown, the sensor device 100 (or the current conductor 2 and/or the electrical contacts 12) can be mechanically and electrically connected to a printed circuit board (PCB) 24. More specifically, the current input 20 of the current conductor 2, the current output 22 of the current conductor 2 and at least one electrical contact 12 of the magnetic field sensor chip 8 can be mechanically and electrically connected to electrically conductive structures 26 on the top side of the printed circuit board 24. In the non-limiting example shown, a solder material 28 can be used for the mechanical or electrical connection. At the corresponding contact points, the current conductor 2 and/or the electrical contacts 12 can be solderable or have solderable surfaces.

The sensor device 200 of FIG. 2 may have some or all of the features of the sensor device 100 of FIG. 1. For the sake of simplicity, not all components of the sensor device 200 are shown in FIG. 2, as are shown, for example, in FIG. 1. In the example shown, the magnetic field sensor chip 8 may be a differential magnetic field sensor chip having a first Hall sensor element 16A and a second Hall sensor element 16B. In the non-limiting example shown, the sensor elements 16A, 16B can be arranged on a surface of the magnetic field sensor chip 8 facing the mounting surface of the busbar 2. In other examples, the sensor elements 16A, 16B may be arranged on a surface of the magnetic field sensor chip 8 facing away from the mounting surface of the busbar 2, as shown and described, for example, in connection with FIG. 1. The two Hall sensor elements 16A, 16B can be sensitive in a direction perpendicular to the mounting surface 10 of the current conductor 2 (e.g., for example, vertically with respect to the chip surface in the z direction). The current conductor 2 may have two slots 30A, 30B on opposite sides of the current conductor 2. The two Hall sensor elements 16A, 16B may be at least partially (and in particular completely) uncovered by the current conductor 2 at the locations of the two slots 30A, 30B. In the example shown, the two slots 30A, 30B can be arranged offset from each other (for example, with respect to the x direction). The current conductor 2 can thus be S-shaped and an electric current flowing through the current conductor 2 can follow an S-shaped course.

The sensor device 300 of FIG. 3 may have some or all of the features of previously described sensor devices. For the sake of simplicity, not all components of the sensor device 300 are shown in FIG. 3, as are shown, for example, in FIG. 1. In contrast, for example, to FIG. 2, the two slots 30A, 30B of the sensor device 300 may be aligned with each other (for example, with respect to the x direction). The current conductor 2 can be I-shaped and an electric current flowing through the current conductor 2 can follow a substantially linear course (for example in the x direction).

The sensor device 400 of FIG. 4 may have some or all of the features of previously described sensor devices. For the sake of simplicity, not all components of the sensor device 400 are shown in FIG. 4, as are shown, for example, in FIG. 1. In the example shown, the magnetic field sensor chip 8 may be a differential magnetic field sensor chip having a first Hall sensor element 16A and a second Hall sensor element 16B. The two Hall sensor elements 16A, 16B can be sensitive in a perpendicular direction (e.g., vertically with respect to the chip surface in the z direction, for example). The current conductor 2 can run between the two Hall sensor elements 16A, 16B. The current conductor 2 can be U-shaped and extend around the first Hall sensor element 16A. Accordingly, an electric current 6 flowing through the current conductor 2 can also have a U-shaped course.

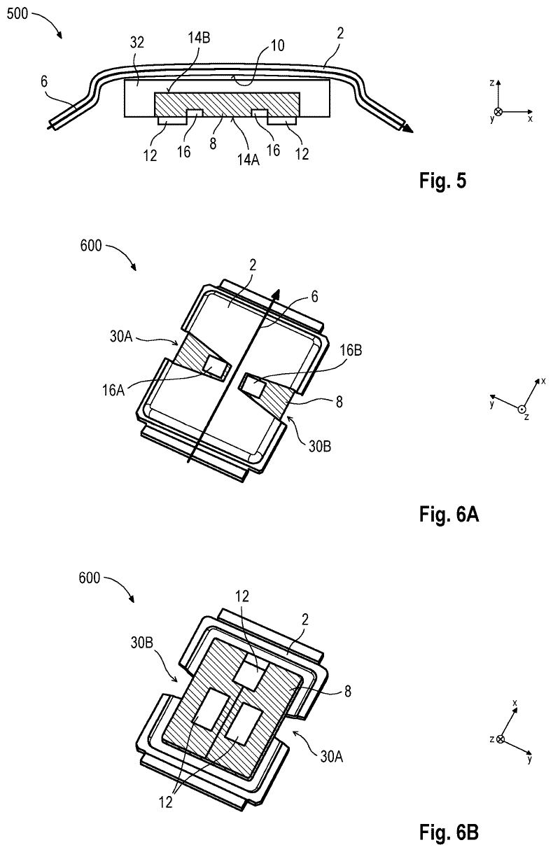

The sensor device 500 of FIG. 5 may have some or all of the features of previously described sensor devices. In particular, the sensor device 500 can be at least partially similar to the sensor device 100 of FIG. 1 and have corresponding components. Explanations relating to FIG. 1 can accordingly also apply to FIG. 5 and are not repeated here for the sake of simplicity. In the example shown, the magnetic field sensor chip 8 may be encapsulated in a housing (or package) 32. The surface 14A of the magnetic field sensor chip 8 facing away from the mounting surface 10 of the current conductor 2 may be uncovered by the housing 32 or the material thereof. In the example shown, the lower surface of the magnetic field sensor chip 8 and the lower surface of the housing 32 may be located substantially in a common plane. The housing 32 with the embedded magnetic field sensor chip 8 can be arranged or secured on the mounting surface 10 of the current conductor 2. Optionally, an adhesion-promoting layer (not shown) can be arranged between the housing 32 and the mounting surface 10, as described, for example, in connection with FIG. 1.

The housing or encapsulation material 32 may in particular contain or be manufactured from an electrically insulating material. For example, the housing 32 may comprise or be produced from at least one of a molding compound, an epoxy, a filled epoxy, an epoxy filled with glass fibers, an imide, a thermoplastic, a thermoset polymer, a polymer mixture, a laminate, or similar. For example, the housing 32 can be based on at least one of compression molding, injection molding, powder molding, liquid molding, map molding, laminating, or similar processes. The housing 32 can be configured to protect the encapsulated components of the sensor device 500 from hazards such as mechanical shocks, chemical contamination, exposure to light, etc. The electrically insulating material of the housing 32 may be arranged at least partially between one or more surfaces (in particular one or more lateral surfaces) of the magnetic field sensor chip 8 and the current conductor 2, in particular to prevent electrical flashovers between these components. The sensor device 500 may also be referred to as a sensor package.

The sensor device 600 of FIGS. 6A and 6B may have some or all of the features of previously described sensor devices. By way of example, the sensor device 600 can be similar to one of the sensor devices 100 and 500 in FIGS. 1 and 5, respectively. FIGS. 6A and 6B show a plan view and a view from below of the sensor device 600. In the example shown, the magnetic field sensor chip 8 may be a differential magnetic field sensor chip having a first Hall sensor element 16A and a second Hall sensor element 16B. In the non-limiting example shown, the sensor elements 16A, 16B can be arranged on a surface of the magnetic field sensor chip 8 facing the mounting surface of the busbar 2. In other examples, the sensor elements 16A, 16B may be arranged on a surface of the magnetic field sensor chip 8 facing away from the mounting surface of the busbar 2, as shown and described, for example, in connection with FIGS. 1 and 5. The two Hall sensor elements 16A, 16B can be sensitive in a direction perpendicular to the mounting surface 10 of the current conductor 2 (e.g., for example, vertically with respect to the chip surface in the z direction). The current conductor 2 may have two slots 30A, 30B on opposite sides of the current conductor 2. The two Hall sensor elements 16A, 16B may be at least partially (and in particular completely) uncovered by the current conductor 2 at the locations of the two slots 30A, 30B. In the example shown, the two slots 30A, 30B (for example, with respect to the x direction) may be aligned with each other. The current conductor 2 can be I-shaped and an electric current 6 flowing through the current conductor 2 can follow a substantially linear course (for example in the x direction). The current conductor 2 may be similar, for example, to the current conductor 2 of FIG. 3.

In the view from below of FIG. 6B, an example and non-limiting number of three electrical contacts 12 of the magnetic field sensor chip 8 is shown. One of the electrical contacts 12 may be configured, for example, to output an (in particular analog) measurement signal of the magnetic field sensor chip 8. For example, the other two electrical contacts can provide a supply voltage connection and a ground connection. However, it should be noted that the number and function of the electrical contacts 12 may differ in other examples and can depend on the individual design of the respective magnetic field sensor chip 8 considered.

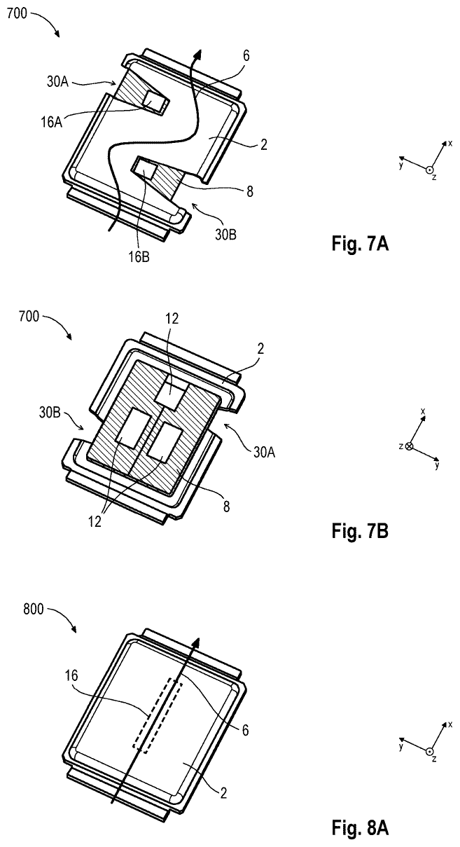

The sensor device 700 of FIGS. 7A and 7B may have some or all of the features of previously described sensor devices. FIGS. 7A and 7B show a plan view and a view from below of the sensor device 700. In contrast to the example of FIGS. 6A and 6B, the two slots 30A, 30B of the sensor device 700 formed in the current conductor 2 may be arranged offset to each other (for example, with respect to the x direction). The current conductor 2 can thus be S-shaped and an electric current 6 flowing through the current conductor 2 can follow an S-shaped course. The current conductor 2 may be similar, for example, to the current conductor 2 of FIG. 2.

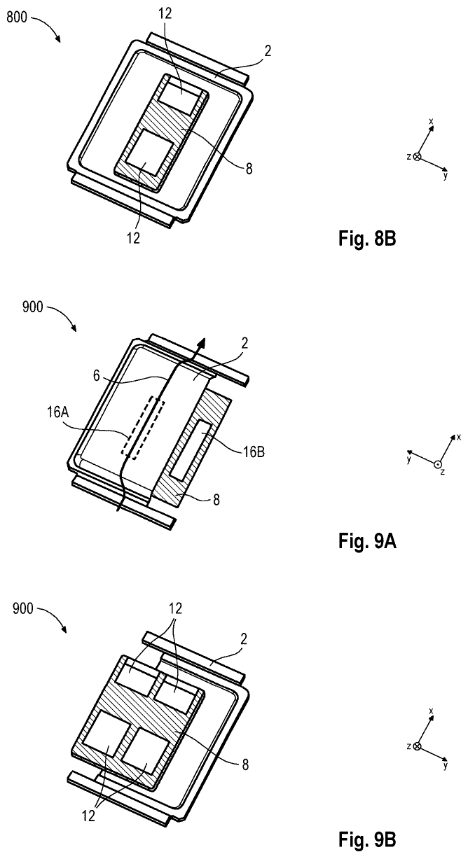

The sensor device 800 of FIGS. 8A and 8B may have some or all of the features of previously described sensor devices. FIGS. 8A and 8B show a plan view and a view from below of the sensor device 800. In the example shown, the magnetic field sensor chip 8 may contain a single magnetoresistive sensor element 16 (for example, an AMR sensor element, a GMR sensor element, or a TMR sensor element). The magnetoresistive sensor element 16 can be sensitive in a direction parallel to the mounting surface 10 of the current conductor 2 (for example, laterally to the chip surface in the x-y plane). In the plan view of FIG. 8A, the magnetoresistive sensor element 16 can be (in particular completely) covered by the current conductor 2 and is therefore shown in dashed lines.

The sensor device 900 of FIGS. 9A and 9B may have some or all of the features of previously described sensor devices. FIGS. 9A and 9B show a plan view and a view from below of the sensor device 900. In the example shown, the magnetic field sensor chip 8 may be a differential magnetic field sensor chip having a first magnetoresistive sensor element 16A and a second magnetoresistive sensor element 16B (for example, AMR sensor elements, GMR sensor elements or TMR sensor elements). The magnetoresistive sensor elements 16A, 16B can be sensitive in each case in a direction parallel to the mounting surface 10 of the current conductor 2 (for example, laterally to the chip surface in the x-y plane). From the plan view of FIG. 9A, it can be seen that the first magnetoresistive sensor element 16A can be (in particular completely) covered by the current conductor 2. The second magnetoresistive sensor element 16B may be (in particular completely) uncovered by the current conductor 2.

The sensor element 16A arranged underneath the current conductor 2 can measure a comparatively large value of the lateral magnetic field component to be detected, while the sensor element 16B arranged next to the current conductor 2 and/or uncovered by the current conductor 2 can measure a very small value of the lateral magnetic field component to be detected. In this respect, the measurement of sensor element 16B can contribute a comparatively small component of the overall measurement result. However, by forming a difference between the two values detected by the sensor elements 16A, 16B, homogeneous stray magnetic fields can be eliminated from the overall measurement result, as is described, for example, in connection with FIG. 10.

In FIG. 10, an example non-limiting concept for measuring an electric current using a sensor device 1000 according to the disclosure is shown. The sensor device 1000 may comprise a current conductor 2 and a magnetic field sensor chip 8 with two sensor elements 16A, 16B. An electric current 6 flowing in the y direction can generate a magnetic field H_{c} in the x-z plane. In the example shown, for the sake of simplicity, only a single field line 34 of the induced magnetic field H_{c} is shown. In addition to the induced magnetic field H_{c}, a magnetic stray field Hₛ (not shown) may occur. In particular, it can be a homogeneous (or spatially homogeneous) magnetic stray field Hₛ, which due to its homogeneity can be substantially identical at the locations of the two sensor elements 16A, 16B. Effectively, at the positions of the first sensor element 16A and the second sensor element 16B, a first magnetic field H₁ or a second magnetic field H₂ may then be present, which are each derived from the vector sum of the magnetic field H_{c} induced by the electric current 6 and the magnetic stray field Hₛ.

The first sensor element 16A may be configured to detect the z component H_{1z} of the first magnetic field H₁ and output a corresponding signal. The following relation may apply:

$${H}_{1 z} = {H}_{c z} + {H}_{s z} \qquad ( 1 )$$

In analogous manner, the second sensor element 16B may be configured to detect the z component H_{2z} of the second magnetic field H₂ and output a corresponding signal. In this case, the following may apply:

$${H}_{2 z} = - {H}_{c z} + {H}_{s z} \qquad ( 2 )$$

It should be noted that the z-component of the induced magnetic field H_{c} in equation (2) must be taken into account with a minus sign (see the arrows pointing up or down for the sensor elements 16A, 16B). The two sensor elements 16A, 16B can each be configured to detect the magnitude and sign of the magnetic field components H_{1z} and H_{2z} respectively.

Forming a difference between the detected components or generating a difference signal between the two output signals can result in the following:

$${H}_{1 z} - {H}_{2 z} = {H}_{c z} + {H}_{s z} - ( - {H}_{c z} + {H}_{s z} ) = 2 {H}_{c z} \qquad ( 3 )$$

Equation (3) shows that the influence of the homogeneous magnetic stray field Hₛ on the two detected first components H_{1z} and H_{2z} can be compensated by forming a difference between the two detected first components H_{1z} and H₂z.

Between the intensity I of the electric current 6 and the difference formed, a proportionality

$$I ∼ {H}_{c z} \qquad ( 4 )$$

can apply. The measurement current I can thus be determined based on the difference formed between the two magnetic field components detected by the sensor device 1000. The sensor device 1000 can therefore also be referred to as a current sensor. The required proportionality factor can be determined, for example, during a calibration of the sensor device 1000 and then taken into account.

The sensor devices described herein according to the disclosure may be technically superior to conventional sensor devices and provide, among other things, the properties described below.

Sensor devices according to the disclosure can be easily constructed from a current conductor and a magnetic field sensor chip mounted therein. Some elements used in conventional sensor devices (e.g., bonding wires) can be omitted. In the case of an unpackaged bare die, no additional encapsulation of the magnetic field sensor chip is required either. Compared to conventional sensor devices, the design of the sensor devices described herein can therefore be greatly simplified, so that cost reductions can be achieved in production.

As shown in the examples described above, there is a high degree of freedom in the design of the current conductor. Different geometric shapes of the current conductor can be easily realized, for example by a deep drawing and/or stamping process.

Sensor devices according to the disclosure are not limited to a specific sensor technology, but can be realized with different magnetic field sensor chip types (e.g., xMR, Hall).

The magnetic field sensor chips contained in the sensor devices described herein may, in particular, have a low overall height, which means a small distance between the current conductor and the sensor elements of the magnetic field sensor chips can be achieved. As a result, the sensor elements can be placed at positions of high magnetic field strength, so that improved measurement results can be achieved by the sensor devices according to the disclosure.

FIG. 11 shows a method for producing a sensor device as claimed in the disclosure. The method can be used, for example, to produce the sensor devices described above. The method is illustrated in a general way in order to explain aspects of the disclosure qualitatively. The method can be extended by one or more aspects which are described in conjunction with other examples described here.

In a step 36, a current conductor with a recess may be formed, wherein the current conductor may be configured to conduct an electric current. In a step 38, a magnetic field sensor chip can be arranged in the recess on a mounting surface of the current conductor, wherein the magnetic field sensor chip can be configured to detect a magnetic field generated by the electric current. The current conductor and the magnetic field sensor chip can be galvanically isolated from each other.

### Examples

Hereinafter, sensor devices according to the disclosure and associated production methods are described using examples.

Example 1 is a sensor device comprising: a current conductor with a recess, wherein the current conductor is configured to conduct an electric current; and a magnetic field sensor chip, which is arranged in the recess on a mounting surface of the current conductor and is configured to detect a magnetic field generated by the electric current, wherein the current conductor and the magnetic field sensor chip are galvanically isolated from each other.

Example 2 is a sensor device according to Example 1, wherein the current conductor has the shape of a shell or a trough and the magnetic field sensor chip is arranged on a bottom surface of the shell or the trough.

Example 3 is a sensor device according to Example 1 or 2, wherein the magnetic field sensor chip is arranged completely in the recess of the current conductor.

Example 4 is a sensor device according to one of the preceding examples, wherein the current conductor is deep-drawn and/or stamped.

Example 5 is a sensor device according to one of the preceding examples, wherein: the magnetic field sensor chip comprises at least one electrical contact, which is arranged on a first surface of the magnetic field sensor chip facing away from the mounting surface, and the magnetic field sensor chip on a second surface of the magnetic field sensor chip facing the mounting surface is free of electrical contacts.

Example 6 is a sensor device according to one of the preceding examples, wherein the magnetic field sensor chip comprises at least one sensor element, which is arranged on a first surface of the magnetic field sensor chip facing away from the mounting surface.

Example 7 is a sensor device according to one of Examples 1 to 5, wherein the magnetic field sensor chip comprises at least one sensor element, which is arranged on a second surface of the magnetic field sensor chip facing the mounting surface.

Example 8 is a sensor device according to Examples 5 and 7, further comprising: an electrical connection which extends from the first surface of the magnetic field sensor chip to the second surface of the magnetic field sensor chip and electrically connects the at least one sensor element to the at least one electrical contact.

Example 9 is a sensor device according to one of the preceding examples, wherein a current input of the current conductor, a current output of the current conductor and at least one electrical contact of the magnetic field sensor chip are arranged in the same plane.

Example 10 is a sensor device according to Example 9, further comprising: a printed circuit board, wherein the current input of the current conductor, the current output of the current conductor and the at least one electrical contact of the magnetic field sensor chip are mechanically and electrically connected to the printed circuit board.

Example 11 is a sensor device according to one of the preceding examples, wherein the sensor device is an SMD device.

Example 12 is a sensor device according to one of the preceding examples, wherein the current conductor and at least one lateral surface of the magnetic field sensor chip are spaced apart from each other.

Example 13 is a sensor device according to one of the preceding examples, wherein the magnetic field sensor chip is an unpackaged bare die.

Example 14 is a sensor device according to one of Examples 1 to 12, wherein: the magnetic field sensor chip is encapsulated in a housing, a surface of the magnetic field sensor chip facing away from the mounting surface is uncovered by the housing, and the housing is arranged on the mounting surface of the current conductor.

Example 15 is a sensor device according to one of the preceding examples, wherein: the magnetic field sensor chip is a differential magnetic field sensor chip having a first Hall sensor element and a second Hall sensor element, wherein the two Hall sensor elements are sensitive in a direction perpendicular to the mounting surface, the current conductor has two slots on opposite sides of the current conductor, and the two Hall sensor elements are at least partially uncovered by the current conductor at the locations of the two slots.

Example 16 is a sensor device according to Example 15, wherein the two slots are aligned with each other and the current conductor is I-shaped.

Example 17 is a sensor device according to Example 15, wherein the two slots are arranged offset to each other and the current conductor is S-shaped.

Example 18 is a sensor device according to one of Examples 1 to 14, wherein: the magnetic field sensor chip is a differential magnetic field sensor chip having a first Hall sensor element and a second Hall sensor element, the two Hall sensor elements are sensitive in a direction perpendicular to the mounting surface, and the current conductor is U-shaped and extends around one of the two Hall sensor elements.

Example 19 is a sensor device according to one of Examples 1 to 14, wherein: the magnetic field sensor chip comprises a single magnetoresistive sensor element which is sensitive in a direction parallel to the mounting surface and is completely covered by the current conductor.

Example 20 is a sensor device according to one of Examples 1 to 14, wherein: the magnetic field sensor chip is a differential magnetic field sensor chip having a first magnetoresistive sensor element and a second magnetoresistive sensor element, wherein the two magnetoresistive sensor elements are sensitive in a direction parallel to the mounting surface, the first magnetoresistive sensor element is covered by the current conductor, and the second magnetoresistive sensor element is uncovered by the current conductor.

Example 21 is a method for producing a sensor device, wherein the method comprises: forming a current conductor with a recess, wherein the current conductor is configured to conduct an electric current; and arranging a magnetic field sensor chip in the recess on a mounting surface of the current conductor, wherein the magnetic field sensor chip is configured to detect a magnetic field generated by the electric current, wherein the current conductor and the magnetic field sensor chip are galvanically isolated from each other.

It should be pointed out that the description and the drawings only illustrate the principles of the proposed methods and devices. A person skilled in the art will be capable of implementing different arrangements which, although they are not expressly described or shown here, embody the principles of the implementation and are contained within the scope thereof. In addition, all examples and implementations outlined in the present document are intended fundamentally and expressly for explanatory purposes only, in order to help the reader understand the principles of the proposed processes and devices. In addition, all statements in this document that describe principles, aspects and implementations of the implementation and specific examples thereof are also intended to encompass their equivalents.

1. A sensor device, comprising:
a current conductor having a recess, wherein the current conductor is configured to carry an electric current; and
a magnetic field sensor chip, which is arranged in the recess on a mounting surface of the current conductor and is configured to detect a magnetic field generated by the electric current,
wherein the current conductor and the magnetic field sensor chip are galvanically isolated from each other.

2. The sensor device as claimed in claim 1, wherein the current conductor has a shape of a shell or a trough, and the magnetic field sensor chip is arranged on a bottom surface of the shell or the trough.

3. The sensor device as claimed in claim 1, wherein the magnetic field sensor chip is arranged completely in the recess of the current conductor.

4. The sensor device as claimed in claim 1, wherein the current conductor is deep-drawn and/or stamped.

5. The sensor device as claimed in claim 1, wherein:
the magnetic field sensor chip comprises at least one electrical contact, which is arranged on a first surface of the magnetic field sensor chip facing away from the mounting surface, and
the magnetic field sensor chip on a second surface of the magnetic field sensor chip facing the mounting surface is free of electrical contacts.

6. The sensor device as claimed in claim 1, wherein the magnetic field sensor chip comprises at least one sensor element, which is arranged on a first surface of the magnetic field sensor chip facing away from the mounting surface.

7. The sensor device as claimed in claim 1, wherein the magnetic field sensor chip comprises at least one sensor element, which is arranged on a second surface of the magnetic field sensor chip facing the mounting surface.

8. The sensor device as claimed in claim 1, wherein the magnetic field sensor chip comprises at least one electrical contact, which is arranged on a first surface of the magnetic field sensor chip facing away from the mounting surface,
wherein the magnetic field sensor chip on a second surface of the magnetic field sensor chip facing the mounting surface is free of electrical contacts,
wherein the magnetic field sensor chip comprises at least one sensor element, which is arranged on the second surface of the magnetic field sensor chip facing the mounting surface, and
wherein the sensor device further comprises:
an electrical connection which extends from the first surface of the magnetic field sensor chip to the second surface of the magnetic field sensor chip and which electrically connects the at least one sensor element to the at least one electrical contact.

9. The sensor device as claimed in claim 1, wherein a current input of the current conductor, a current output of the current conductor and at least one electrical contact of the magnetic field sensor chip are arranged in a same plane.

10. The sensor device as claimed in claim 9, further comprising:
a printed circuit board, wherein the current input of the current conductor, the current output of the current conductor and the at least one electrical contact of the magnetic field sensor chip are mechanically and electrically connected to the printed circuit board.

11. The sensor device as claimed in claim 1, wherein the sensor device is surface mounted device (SMD) device.

12. The sensor device as claimed in claim 1, wherein the current conductor and at least one lateral surface of the magnetic field sensor chip are spaced apart from each other.

13. The sensor device as claimed in claim 1, wherein the magnetic field sensor chip is an unpackaged bare die.

14. The sensor device as claimed in claim 1, wherein:
the magnetic field sensor chip is encapsulated in a housing,
a surface of the magnetic field sensor chip facing away from the mounting surface is uncovered by the housing, and
the housing is arranged on the mounting surface of the current conductor.

15. The sensor device as claimed in claim 1, wherein:
the magnetic field sensor chip is a differential magnetic field sensor chip having a first Hall sensor element and a second Hall sensor element,
wherein the first Hall sensor element and the second Hall sensor element are sensitive in a direction perpendicular to the mounting surface,
the current conductor has two slots on opposite sides of the current conductor, and
the first Hall sensor element and the second Hall sensor element are at least partially uncovered by the current conductor at locations of the two slots.

16. The sensor device as claimed in claim 15, wherein the two slots are aligned with each other and the current conductor is I-shaped.

17. The sensor device as claimed in claim 15, wherein the two slots are arranged offset to each other and the current conductor is S-shaped.

18. The sensor device as claimed in claim 1, wherein:
the magnetic field sensor chip is a differential magnetic field sensor chip having a first Hall sensor element and a second Hall sensor element,
the first Hall sensor element and the second Hall sensor element are sensitive in a direction perpendicular to the mounting surface, and
the current conductor is U-shaped and extends around one of the first Hall sensor element or the second Hall sensor element.

19. The sensor device as claimed in claim 1, wherein:
the magnetic field sensor chip comprises a single magnetoresistive sensor element which is sensitive in a direction parallel to the mounting surface and is completely covered by the current conductor.

20. The sensor device as claimed in claim 1, wherein:
the magnetic field sensor chip is a differential magnetic field sensor chip having a first magnetoresistive sensor element and a second magnetoresistive sensor element,
wherein the first magnetoresistive sensor element and the second magnetoresistive sensor element are sensitive in a direction perpendicular to the mounting surface,
the first magnetoresistive sensor element is covered by the current conductor, and
the second magnetoresistive sensor element is uncovered by the current conductor.

21. A method for producing a sensor device, wherein the method comprises:
forming a current conductor with a recess, wherein the current conductor is configured to conduct an electric current; and
arranging a magnetic field sensor chip in the recess on a mounting surface of the current conductor, wherein the magnetic field sensor chip is configured to detect a magnetic field generated by the electric current,
wherein the current conductor and the magnetic field sensor chip are galvanically isolated from each other.
